(19) United States
(12) Patent Application Publication
(10) Pub. No.: US 2008/0138927 A1
(43) Pub. Date: Jun. 12, 2008

(54) Systems and Methods for Fabricating Crystalline Thin Structures Using Meniscal Growth Techniques

(75) Inventor: Randall L. Headrick, Burlington, VT (US)

Correspondence Address: DOWNS RACHLIN MARTIN PLLC, 199 MAIN STREET, P O BOX 190, BURLINGTON, VT, 05402-0190, US

(73) Assignee: The University of Vermont and State Agricultural College, Burlington, VT (US)

(21) Appl. No.: 11/968,386

(22) Filed: Jan. 2, 2008

Related U.S. Application Data
(63) Continuation-in-part of application No. 11/078,544, filed on Mar. 11, 2005, now Pat. No. 7,351,283.
(60) Provisional application No. 60/552,135, filed on Mar. 11, 2004.
(60) Provisional application No. 60/946,421, filed on Jun. 27, 2007.

(51) Int. Cl. H01L 21/00; C30B 7/00

(52) U.S. Cl. 438/97; 117/23; 117/223; 257/E21.001

(57) ABSTRACT

Systems and methods that utilize semiconductor molecules to form crystalline thin-films by depositing the molecules into a substrate at a lateral growth front. Techniques embodied in corresponding ones of the disclosed systems and methods include a submersion technique in which a substrate is submerged in a precursor solution containing the molecules and a film is grown at a meniscus formed between the free surface of the solution and the substrate. Another disclosed technique is a mask technique in which a film is grown on a substrate through an aperture of a moving mask be exposing the aperture to the molecules. Yet another technique disclosed is a writing technique in which a pen is used to deliver to a substrate a precursor solution containing the molecules and the film is grown as the solvent evaporates from the delivered solution.

### RELATED APPLICATION DATA

This application is a continuation-in-part of U.S. patent application Ser. No. 11/078,544, filed on Mar. 11, 2005 (now U.S. Pat. No. ______), which claims the benefit of priority of U.S. Provisional Patent Application Ser. No. 60/552,135, filed Mar. 11, 2004, and titled “Method for Fabricating Thin Film and Thin Wire-Like Structures.” This application also claims priority to U.S. Provisional Patent Application Ser. No. 60/946,421, filed Jun. 27, 2007, and titled “System and Method for Fabricating Crystalline Thin Structures and Electronic Circuits.” Each of these applications is incorporated herein by reference in its entirety.

### FIELD OF THE INVENTION

The present invention generally relates to the field of fabricating crystalline structures. In particular, the present invention is directed to systems and methods for fabricating crystalline thin structures using meniscal growth techniques.

### BACKGROUND OF THE INVENTION

Virtually every large electronics company is presently engaged in research in the area of organic electronics. Specific applications include organic thin film transistors (OTFTs), organic light-emitting devices (OLEDs), electro-luminescent displays, RF identification tags, and low-cost photovoltaic devices for solar power generation. Some close to the electronics industry predict that organic microelectronics will eventually displace inorganic microelectronics in the realm of computer and other displays, particularly flat panel displays. The reason cited for this change is that organic microelectronics can utilize flexible and lightweight material, whereas conventional flat panel displays, for example, liquid crystal displays (LCDs) and plasma displays, typically require relatively heavy and rigid substrates and other components.

Current issues that need to be addressed for widespread commercialization of organic electronics include: 1) low-cost, high-throughput methods to produce thin film materials and 2) methods to produce high-quality materials composed of large crystalline domains. For example, conventional methods of depositing organic semiconductor thin films routinely produce materials that have crystalline domain sizes smaller than 10 microns. Consequently, it would be desirable for many reasons for manufacturers to be able to make high-quality organic films having crystalline domains several orders of magnitude larger than conventionally practicable and even more desirable if manufacturers were able to achieve such large crystalline domain sizes at a low cost.

### SUMMARY OF THE INVENTION

In a first implementation, a method of growing a crystalline structure of a semiconductor material. The method includes: providing a substrate that includes a growth region on which the crystalline structure will be formed; providing a solution of dissolved molecules of the semiconductor material; forming, with the solution, a meniscus on the growth region; establishing, at the meniscus, an initial lateral seed front on the growth region; and mechanically moving the meniscus relative to the growth region in a growth direction along the growth region so as to substantially continuously grow the crystalline structure on the growth region in the growth direction by first adding ones of the dissolved molecules to the initial lateral seed front to create a lateral growth front and then continually adding more of the dissolved molecules to the lateral growth front.

In another implementation, the present invention is directed to a method of fabricating a crystalline thin structure of a semiconductor material. The method includes: providing a substrate having a surface; providing a solution containing dissolved molecules of the semiconductor material of the elongate crystalline structure to be fabricated; delivering the solution to a meniscal pen; and writing a crystalline structure of the semiconductor material on the surface of the substrate using the meniscal pen.

In a further implementation, the present invention is directed to a system for fabricating a crystalline structure of a semiconductor material on a substrate. The system includes: a reservoir for holding a solution containing dissolved molecules of the semiconductor material; a meniscal pen having a meniscal region for delivering the solution from the reservoir to the substrate via a meniscus formed between the meniscal region and the substrate; and a mechanism for controllably moving the meniscus relative to the substrate so as to form the crystalline structure on the substrate.

In still a further implementation, the present invention is directed to a method of fabricating an electronic device. The method includes: providing a substrate; providing a solution containing dissolved molecules of a semiconductor material; forming an electrical device on the substrate, the electrical device having a crystalline semiconductor component, the forming of the electrical device including writing the crystalline semiconductor component; forming other components of the electrical device; and electrically connecting to electronic device to one or more other electrical devices aboard the substrate.

### BRIEF DESCRIPTION OF THE DRAWINGS

For the purpose of illustrating the invention, the drawings show aspects of one or more embodiments of the invention. However, it should be understood that the present invention is not limited to the precise arrangements and instrumentalities shown in the drawings, wherein:

FIG. 1A is a cross-sectional elevational view and corresponding detail of a submersion-type crystalline thin structure growing (CTSG) system made in accordance with concepts of the present invention;

FIG. 1B is a cross-sectional elevational view of an alternative submersion-type CTSG system made in accordance with concepts of the present invention utilizing a solution drawdown pump for lowering the free surface of the solution during crystal growth;

FIG. 1C is a cross-sectional elevational view of another alternative submersion-type CTSG system made in accordance with concepts of the present invention utilizing a solution displacing system for lowering the free surface of the solution during crystal growth;

FIG. 2 is a cross-sectional view of a mask-type CTSD system made in accordance with concepts of the present invention that utilizes a lateral growth front mask to control the growth of the thin film structure;

FIG. 3 is a high-level block diagram of an electronic device comprising a plurality of organic microelectronic elements made in accordance with concepts of the present invention;

FIG. 4 is a photograph of an Anthracene film grown on a glass slide using a submersion-type CTSG system made in accordance with concepts of the present invention, the film having a domain size greater than 1 cm by 1 cm;

FIG. 5 is a fluorescence micrograph and an inset polarized light microscopy photograph showing an Anthracine film grown using a submersion-type CTSG system made in accordance with concepts of the present invention at a rate of approximately 5 cm/hr;

FIG. 6 is a plot of an x-ray diffraction θ-2θ scan of the film of FIG. 5;

FIG. 7 is a plot of an x-ray diffraction scan performed in situ during epitaxial deposition of Pentacene on the film of FIG. 5;

FIG. 8 is a composite of a plot of an x-ray diffraction scan for the (200) reflection of the Pentacene deposited relative to FIG. 7, a plot, and an enlarged plot, of an azimuthal x-ray diffraction scan on the (200) reflection of the Antracene film onto which Pentacene was deposited, and a stereographic projection;

FIG. 9A is a partial elevational view/partial schematic view of a writing-type CTSG system made in accordance with concepts of the present invention; FIG. 9B is a plan view of the substrate of FIG. 9A illustrating a plurality of thin crystalline lines drawn using the CTSG system of FIG. 9A;

FIG. 10 is a polarized visible-light micrograph of 0.9 mm×0.9 mm area of a 1 mm wide thin-film line of triisopropylsilyl-pentacene grown on a gold thin film using a writing-type CTSG system made in accordance with concepts of the present invention, wherein the line was drawn from the bottom to the top of the image;

FIG. 11A is an idealized cross-sectional view of an organic field effect transistor (OFET) made using a writing-type CTSG system made in accordance with concepts of the present invention;

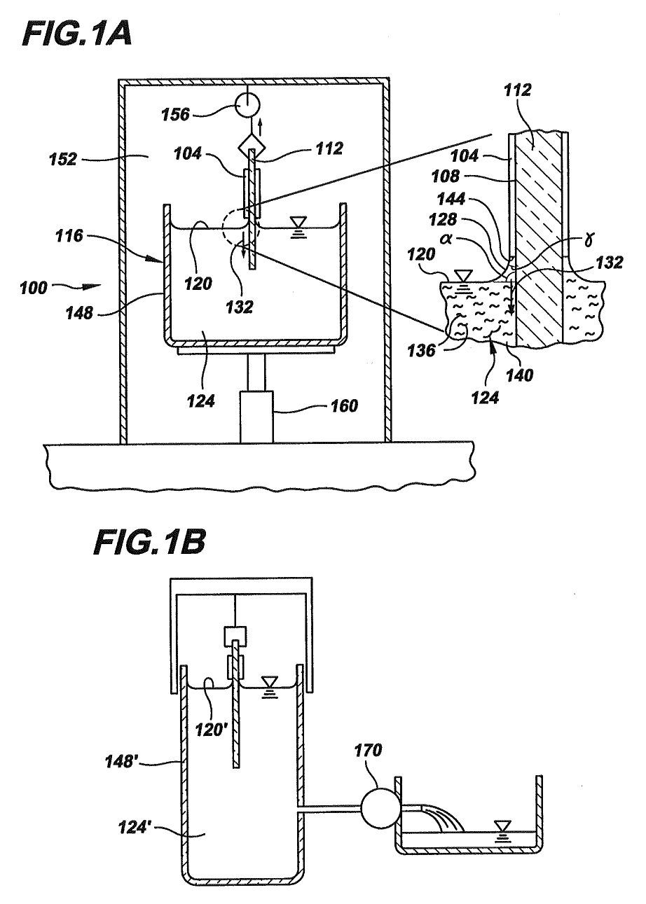

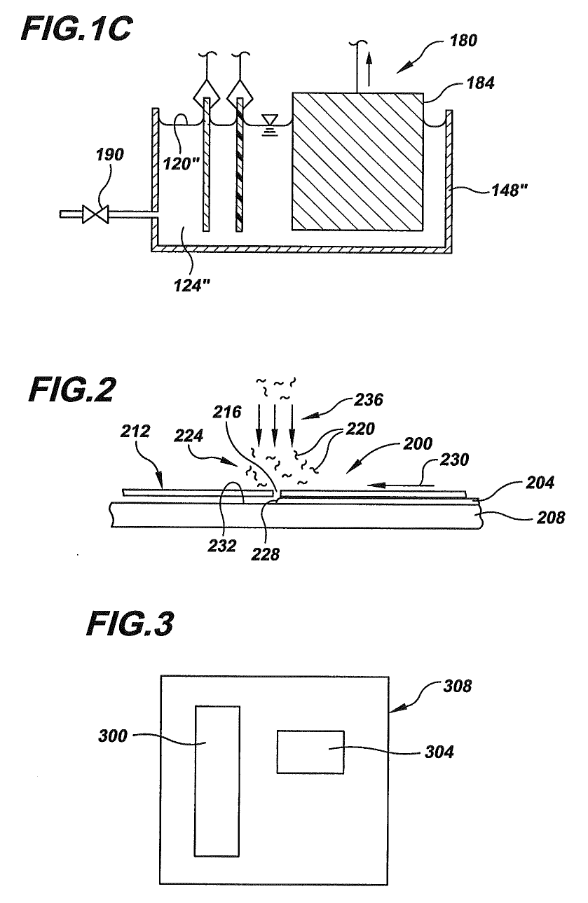

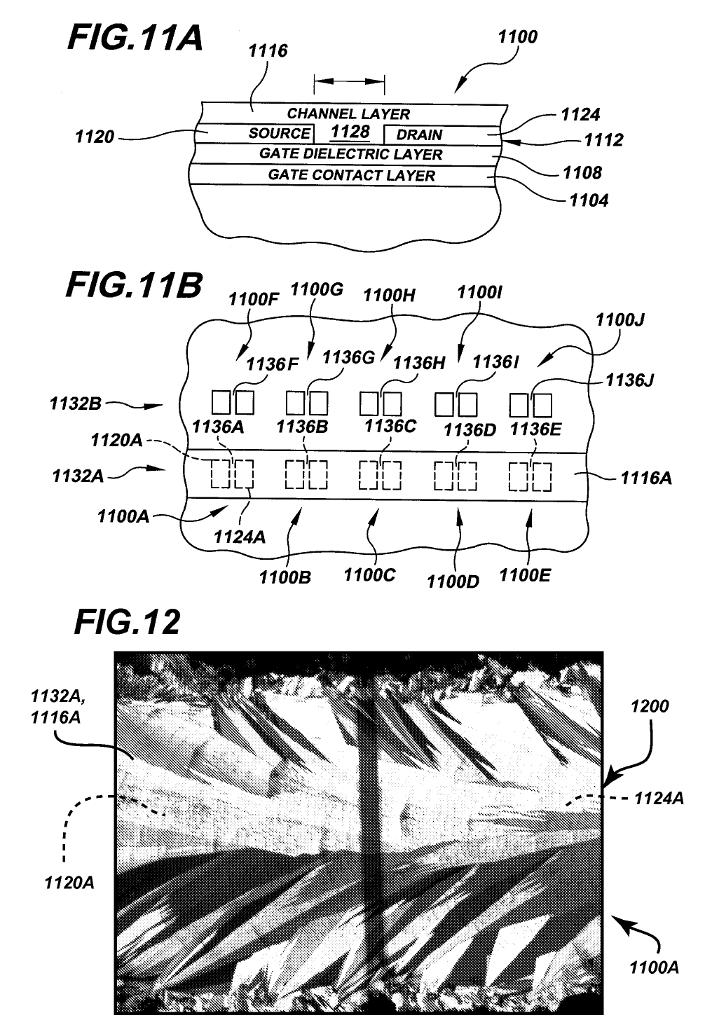

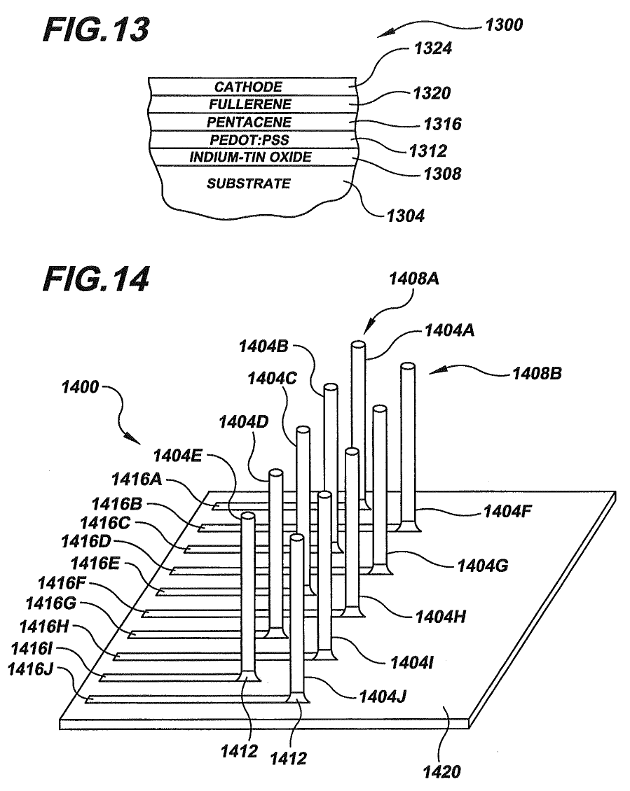

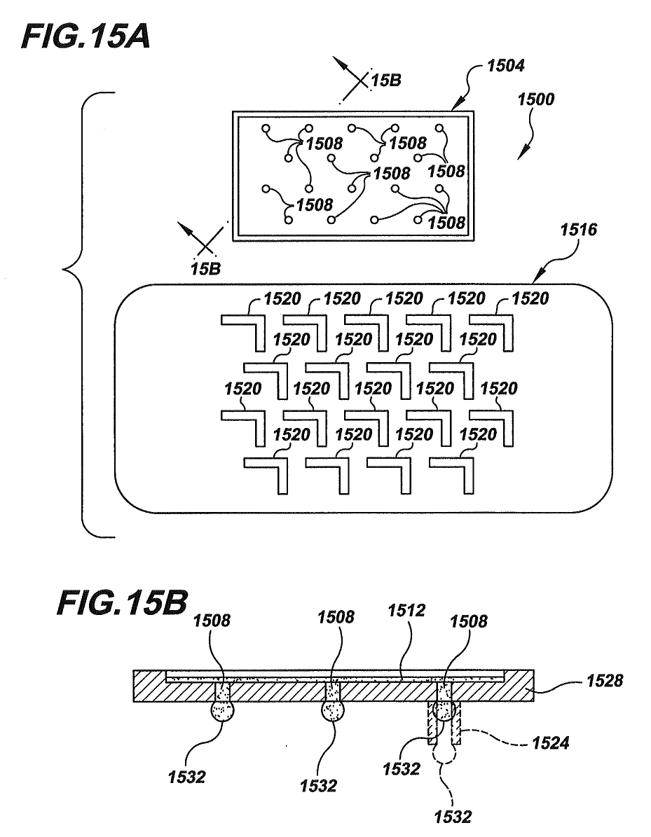

FIG. 1B is a reduced plan view of a plurality of OFETs having the construction of the OFET of FIG. 11A, illustrating how the channel layers of the OFETs can be deposited using a writing technique of the present invention;

FIG. 12 is a polarized visible-light micrograph of a 1.75 mm×1.25 mm area of a 1 mm wide thin-film line of triisopropylsilyl-pentacene grown on a gold thin film using the writing-type CTSG system made in accordance with concepts of the present invention, wherein the line was drawn from the left to the right of the image;

FIG. 13 is an idealized cross-sectional view of a photovoltaic cell made using a CTSG technique of the present disclosure;

FIG. 14 is a perspective view of an alternative writing-type CTSG system made in accordance with concepts of the present invention that includes multiple capillary pens; and

FIG. 15A is a side-by-side top view of a multi-meniscus pen and a top view of a substrate that has been written on using the multi-meniscus pen; and FIG. 15B is an enlarged cross-sectional view of the multi-meniscus pen of FIG. 15A as taken along line 15B-15B of FIG. 15A.

### DETAILED DESCRIPTION OF THE DRAWINGS

As will be discussed below in the context of three exemplary implementations, concepts of the present invention are directed to systems and methods for growing thin crystalline structures using unique crystal-growth techniques. In general, these techniques utilize a solution containing precursor molecules to the crystalline structures and involve growing the structures by ordered growth of the structures at a lateral growth front from the addition of the molecules from the solution to the growing structure. Techniques of the present invention can be implemented in a variety of ways, including the submersion-type, mask-type, and writing-type implementations described below. Implementations of concepts of the present invention, including the implementations just mentioned address, among other things, the needs noted in the Background section above for low-cost, high throughput methods for producing organic-film based structures and methods for producing high-quality structures composed of large crystalline domains. For example, various instantiations of such implementations can be very inexpensive to make and are amenable to scaling up for high-throughput manufacturing. In addition and as mentioned, conventional methods of depositing organic semiconductor thin films routinely produce materials that have crystalline domain sizes smaller than 10 microns. Implementations of the concepts of the present invention, on the other hand, can improve on that by several orders of magnitude. These and other benefits of the present invention will become apparent from reading and understanding the entire present disclosure.

### Submersion-Type Implementation

Referring now to the drawings, FIG. 1A shows in accordance with the present invention a crystalline thin structure growing (CTSG) system, which is generally indicated by the numeral 100. As will become apparent from reading the following disclosure, the word “structure” as used herein and in the appended claims encompasses the various structures, for example, structure 104, deposited using a CTSG method of the present invention. Such structures include films, dendritic structures, elongate “wire-like” structures, lattice structures and films with single-molecule thickness, among others. It is further noted from the outset that the crystalline growth of the present invention is conducted at a molecular scale, as distinct from prior art crystalline growth that has been performed at the much larger scale of synthetic microspheres, as has been reported for micron-sized silica spheres from a colloidal suspension.

A CTSG system of the present invention, such as submersion-type CTSG system 100, may be used to laterally grow crystalline thin structures, such as structure 104, on a growth surface 108 of a substrate 112 at a thickness of one molecule of the deposited material (e.g., about 2 nm for Anthracene) to about 5 μm, in a direction perpendicular to the growth surface. A more typical range of thicknesses is one molecule up to about 1 μm. For example, a CTSG system of the present invention may be used to grow organic crystalline thin structures on many different surfaces regardless of whether or not the corresponding substrate is crystalline, polycrystalline or non-crystalline, i.e., amorphous. Such structures are generally important, for example, in the field of organic electronics because charge conduction in organic materials typically requires very high electric fields (e.g., 10⁴ V/cm to 10⁶ V/cm). Therefore, in order to operate at relatively low voltages, the organic structures must be very thin. Consequently, the present invention is particularly suited to the field of organic electronics. That said, those skilled in the art will readily appreciate that the present invention is by no means limited to this field.

In general, submersion-type CTSG system 100 of FIG. 1A comprises a crystal grower 116 configured to perform one particular type of CTSG method of the present invention. In general terms, this type of CTSG method involves submerging growth surface 108 of substrate 112 through a free surface 120 of a precursor solution 124 and moving one, the other, or both of the growth surface and the free surface relative to the other so that the upper edge of the meniscus 128 at the substrate traces a trajectory 132 along the growth surface. As those skilled in the art will appreciate, in order to satisfy this trajectory requirement when growth surface 108 is planar, the angle α formed between the growth surface and free surface 120 of solution 124 may generally be any angle greater than 0° and less than 180°, with angles close to, and at, 90° being more typical. A number of ways to cause the upper edge of meniscus 128 to trace trajectory 132 are discussed below.

Precursor solution 124 generally comprises molecules 136 of the material of crystalline thin structure 104 dissolved in a suitable solvent 140. As the upper edge of meniscus 128 traces trajectory 132, crystalline thin structure 104 grows along a lateral growth front 144 as dissolved molecules 136 from solution 124 continually condense into solid form at the lateral growth front immediately adjacent the upper edge of the meniscus. Generally, molecules 136 are added to growth front 144 substantially individually, for example, singly or in groups of 10 or fewer molecules, as distinguished, for example, from conventional growth of crystals from silica microspheres, in which each microsphere contains hundreds of thousands of molecules.

Briefly, growth generally occurs when solvent 140 in solution 124 evaporates and free surface 120 of the solution is otherwise moved relative to growth surface 108 and solution flows into the region of meniscus 128 in order to maintain the shape of the meniscus. Dissolved molecules 136 are carried along and concentrate in that region. As free surface 120 lowers and/or substrate 112 is withdrawn, for example, by evaporation or by external control, the dissolved molecules 136 condense into a solid. The so-far deposited crystalline thin structure 104 subsequently “seeds” growth on lateral growth front 144 at each subsequent position of meniscus 128 relative to growth surface 108, and the method continues, ultimately coating the entire wetted portion of the growth surface with a substantially uniform crystalline layer. The rate at which structure 104 is deposited, or grown, shall be referred to hereinafter as “growth rate.” In general, the growth rate may be precisely controlled and is a function of, among other things, the speed at which free surface 120 and growth surface 108 move relative to one another.

Growing crystalline thin structures of organic semiconductor materials have been the primary focus of uses of concepts of the present invention because they are of significant current interest. Materials that may be deposited using the present invention include crystalline forms of Anthracene, Tetracene and Pentacene. However, those skilled in the art will readily appreciate that the present invention can be used to deposit a wide variety of materials. Examples of other materials that may be deposited to form a crystalline thin structure, such as structure 104, include, but are not limited to, derivatives of Pentacene, Anthracene and Tetracene formed by organic synthesis, poly (3-hexylthiophene) and poly(2,5-thienylene vinylene), among many others.

Solution 124 may be formulated by mixing an appropriate amount of precursor molecular solute, i.e., molecules 136 of the material to be deposited, such as molecules Anthracene, Tetracene and Pentacene, etc., with an appropriate amount of a suitable solvent 140, for example, ethyl acetate, toluene and chlorinated solvents, among many others. Those skilled in the art will readily understand that due to the wide variety of precursor molecular solutes and solvents that may be used in connection with the present invention it is impractical, and not necessary, to provide exhaustive lists of all such components in order for those skilled in the art to practice the present invention to its fullest scope. In general, the concentration of precursor molecular solute, i.e., molecules 136, may be any value between 0% and 100% suitable for achieving the desired growth rates and type of structure(s) 104 desired. Concentrations for a few precursor molecular solutes that have been investigated so far are discussed below. Those skilled in the art will readily appreciate that the concentrations discussed below are not limiting, but rather are merely exemplary.

Solution 124 may be contained within virtually any container 148 suitable for holding this solution. As will be readily appreciated by those skilled in the art, there are numerous ways to effect the relative movement of free surface 120 of solution and substrate 112. For example, substrate 112 may be fixed relative to container 148 and free surface 120 lowered by natural evaporation of solvent 140 within solution 124 into an uncontrolled ambient environment (not shown). In alternative embodiments, the evaporation of solvent 140 may be controlled by suitably controlling one or more aspects of a closed environment 152 to which free surface 120 is exposed and/or controlling one or more aspects of solution 124 itself. For example, the temperature, pressure and gas/vapor composition within closed environment 152 may be controlled, as may be the temperature of solution 124, among other things, so as to control the evaporation of solvent 140.

In addition, or alternatively, to controlling closed environment 152 and/or the temperature of solution 124, one or both of substrate 112 and container 148 may be supported by a corresponding respective actuator 156, 160 that moves the respective component relative to the other. Each actuator 156, 160 may be any suitable type of actuator, such as an electrical, mechanical, pneumatic or hydraulic type, or any combination of these. Those skilled in the art will readily understand how to select an appropriate actuator 156, 160 based on the speed and precision needed for a particular design.

Examples of other ways in which free surface 120 of solvent 124 and/or substrate 112 may be moved relative to the other include utilizing a drawdown pump 170 (FIG. 1B) to controllably pump solution 124′ from container 148′ at a desired rate so as to lower the free surface 120′ within the container, utilizing a solution displacement system 180 (FIG. 1C) in which a displacer 184 is controllably withdrawn from the solution 124″ so as to cause free surface 120″ to lower within container 148″, utilizing a valve 190 (FIG. 1C) to controllably release the solution from the container so as to lower the free surface and utilizing a variable volume container (not shown), for example, one in which a bottom or sidewall moves relative to the others, in which the volume can be increased so as to cause the free surface to lower, among others. Of course, any two or more of these and the other ways of causing relative movement between free surface 120 (FIG. 1A) and substrate 112 may be used in concert with one another to achieve the desired growth rate.

Referring again to FIG. 1A, substrate 112 may be made of virtually any material or combination of materials. For example, substrate 112 may be monolithic and may be, for example, glass, polymeric or metal, among many others. Substrate 112 may alternatively be made of two or more materials, for example, a different material for each of a plurality of layers. For example, one layer may be of one broad class of materials, for example, polymer, conductive, etc., while the other may be of another class, for example, metal, non-conductive, etc. In one particular example discussed below, substrate 112 includes a silicon layer having an oxided and hydrogen-terminated surface layer (not shown). Again, substrate 112 need not be crystalline in nature, but rather may be amorphous.

A number of additions/modifications to a CTSG method made in accordance with concepts of the present invention may be made. For example, in some applications it may be desirable to intentionally modify the wettability of growth surface 108 so as to improve the growth of structure 104 thereon. In general, wettability determines the contact angle γ of meniscus 128. Variation of contact angle γ may, in turn, modify the thickness and/or uniformity of the resulting thin structure 104. This can be achieved, for example, by use of a surfactant, or by treating growth surface 108 with a self-assembled monolayer, or other coating. In the case of silicon dioxide, the wettability is improved using a base treatment that modifies the chemical termination of the silicon dioxide structure.

### Mask-Type Implementation

Referring to FIG. 2, another modification of a CTSG method of the present invention involves utilizing an alternative type of lateral-growth crystal grower 200 to vacuum deposit a crystalline thin structure 204 on a substrate 208. In this embodiment, crystal grower 200 comprises a mask 212 having at least one opening, for example, slit 216, through which molecules 220 from a molecular precursor 224 are deposited at the growth front 228 through the opening while the opening and/or substrate are moved relative to the other at a controlled rate, for example, 10 cm/hr or less. For example, mask 212 may be moved in direction 230, while substrate 208 remains fixed. Mask 212 masks the growth surface 232 and already deposited crystalline thin structure 204 except at slit 216, which is generally used to define moving growth front 228. Molecular precursor 224 may be in the form of a directed molecular beam 236 produced in vacuum. Characteristics of molecular beam 236 are typically no different from a conventional molecular beam. The size of the molecular beam source (not shown) and the distance between slit 216 and substrate 208 should be adjusted so that the slit forms a sharp shadow of the incident molecular beam 236 on substrate 208. The penumbra of the shadow should be no larger than about 1 μm, so that for a source-to-substrate distance of 500 mm, and a source size of 1 mm, slit 216 should be placed within 0.5 mm of the substrate. In this modification, the basic growth mechanism of the method is still the same as with crystal grower of FIG. 1A, i.e. lateral seeding of a growing crystallite. However, this modified CTSG method of the present invention eliminates the need for a solvent and, consequently, may be considered a more versatile method.

As mentioned above and referring to FIG. 3, organic microelectronics, such as organic microelectronic circuits 300, 304, have potential applications in a number of low-cost electronic devices, such as electronic device 308. Electronic device 308 may be virtually any microelectronics-based device, such as a flat panel display, memory or microprocessor, among many others. It is envisioned that electronic device 308 will typically be based on organic thin film transistors (OTFTs) (not shown) and other organic-based microelectronic electrical devices. For the sake of clarity, here, the distinction between “electrical devices” and “electronic devices” is noted. As used herein and in the appended claims, the terms “electrical devices” and “electrical device” denote individual circuit-level devices that provide basic functionality, such as transistors, diodes, photovoltaic cells, photoreceptors, light-emitting diodes, and chemical sensors, among others. The terms “electronic devices” and “electronic device,” on the other hand, denote high-level devices that each include one or more integrated circuits that together and/or in combination with other components provide one or more high-level functions. Examples of electronic devices include, among many others, flat panel video monitors and other electronic displays, cell phones, personal digital assistants, and sensor arrays.

A CTSG system of the present invention, such as any one of CTSG systems 100, 200, 900, 1400 of FIGS. 1A-1C, 2, 9 and 14, respectively, can be used, for example, to make organic microelectronic circuits 300, 304. As will become apparent from the below descriptions of thin-film transistor 1100 of FIG. 11 and photovoltaic cell 1300 of FIG. 13, a CTSG method of the present invention may be used at any one or more steps of a fabrication method used to make a particular electrical device. For example, once an initial crystalline thin structure, for example, a film, has been grown in accordance with any one of the methods of the present invention, one or more subsequent layers, for example, epitaxial and/or amorphous layers, may be deposited upon the initial layer to complete the electrical devices and corresponding microelectronic circuits 300, 304. In other examples, one or more initial layers of conventional formation will be provided before forming one or more crystalline thin structure layers in accordance with any of the methods of the present invention. As those skilled in the art will appreciate, one or more additional conventionally formed layers/structures and/or one or more crystalline thin structure layers in accordance with concepts of the present invention may also need to be provided prior to finishing the particular electrical devices and corresponding microelectronic circuits 300, 304. Growth of a hetero-epitaxial layer is illustrated below. Additional detail regarding device 308 and microelectronic circuits 300, 304 is not necessary, since those skilled in the art will understand how to build such items and understand the role of the present invention in making these items.

Among the various materials suitable for OTFTs and microelectronic circuits 300, 304 in general, Pentacene stands out as a model molecule, since it has the largest field effect mobility reported so far. This has motivated a number of studies of organic semiconductor growth on dielectrics, as well as other substrates. Recently, significant progress has been made towards fabricating high quality, large-grain, polycrystalline films of Pentacene. Of course, it is recognized that compositions other than Pentacene may indeed be found suitable for use in connection with concepts of the present invention.

### Examples of Submersion-Type CTSG

As discussed below, excellent results have been obtained using a submersion-type CTSG method of the present invention to grow crystalline Anthracene structures on a variety of substrates, including glass substrates, oxidized silicon substrates, and polymer substrates. As mentioned above, by controlling submersion-type method parameters, a variety of deposited structure morphologies may be formed, including continuous films and separated wire-like structures with individual widths as small as a few microns. Single-crystal domains have approached the length of the sample in one direction, up to 75 mm in experiments to date. A practical advantage of a submersion-type CTSG method of the present invention in particular is the ability to cover relatively large areas easily without resorting to a vacuum environment. To date, crystalline thin structures having a domain size of about 0.7 cm×0.7 cm have been grown using a CTSG method of the present invention. It is expected that larger and larger domain sizes will be achieved with further refining of deposition parameters.

Anthracene (C₁₄H₁₀) has a monoclinic structure with lattice constants a=8.561 Å, b=6.036 Å, c=11.163 Å and β=124° 42′. The structure is composed of layers of molecules stacked along the c-direction with “herringbone” packing within each layer. The (001) surface has the lowest free energy and, as a result, when a thin film of Anthracene is formed the a and b lattice vectors are typically in the plane of the film. Individual molecules in the film stand nearly upright with respect to the surface, but “lean over” by an angle χ=β-90°=34.6° from the surface normal.

Referring to FIG. 1A, in one set of experiments, several Anthracene structures (in this case films) were deposited from a 50% saturated solution 124 of Anthracene (i.e., precursor molecular solute, or molecules 136) in ethyl acetate (i.e., solvent 140). Two variations of a submersion-type CTSG method of the present invention were used. In the first variation, 75 mm by 25 mm samples of glass and silicon substrates (112) were placed upright in a staining jar, i.e., container 148, containing solution 124. Each staining jar held four samples upright simultaneously. Solution 124 was allowed to evaporate over a period of 8 hours to 12 hours. In the second variation, a 600 mL beaker was used as container 148, and an oxidized silicon substrate 112 was suspended upright using a fixture to hold the sample from its upper end. A peristaltic pump (see, e.g., pump 170 of FIG. 1B) (model no. RP-1 available from Rainin Instrument Co. Inc., Emeryville, Calif.) was used to gradually remove solution from the beaker so as to lower the free surface of the solution relative to the silicon substrate at a controlled growth rate. Several experiments were conducted at a controlled growth rate ranging between about 1 cm/hr and about 5 cm/hr. All samples were subsequently examined with an optical microscope using fluorescence microscopy and polarized-light microscopy, with illumination from a mercury lamp. Selected samples were examined with x-ray diffraction.

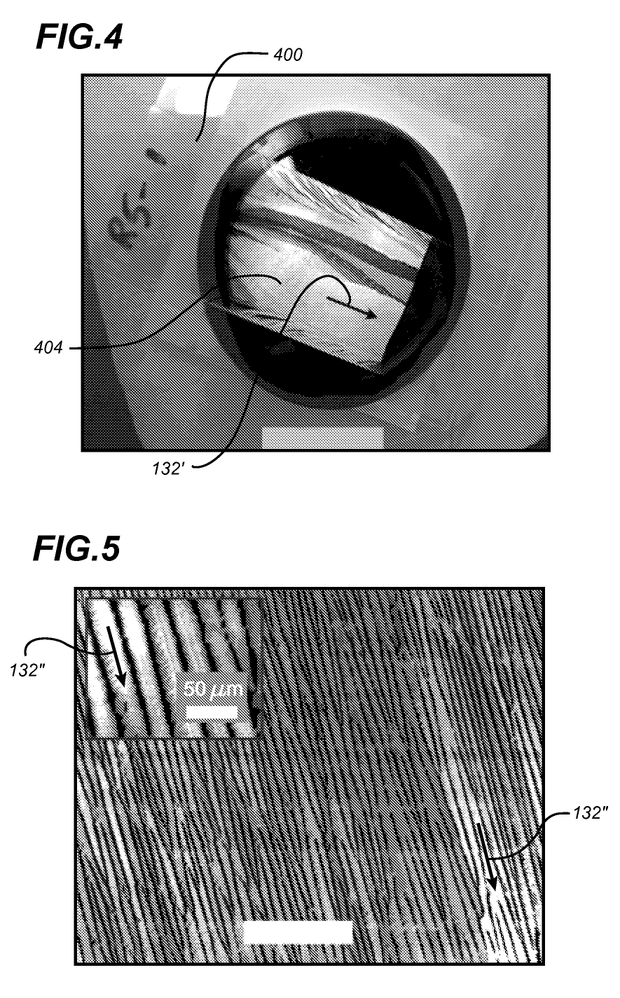

Referring to FIG. 4, and also to FIG. 1A for components of the CTSG system not shown in FIG. 4, in a particular example of the first variation of the submersion-type CTSG method mentioned above a glass microscope slide 400 (corresponding to substrate 112) was placed vertically in a staining jar (container 148) containing a solution (solution 124) of Anthracene (molecules 136) and ethylene acetate (solvent 140). As the solution slowly evaporated, the meniscus of the solution moved across the surface (growth surface 108) of slide 400 toward the lower edge of the slide and depositing a thin film 404 (corresponding to crystalline thin structure 104) of Anthracene on the surface of the slide. Anthracene film 404 produced was colorless and virtually perfectly transparent. For the photograph of FIG. 4, the image of Anthracene film 404 was captured through crossed polarizers with illumination from behind the film. Anthracene film 404 induced a large rotation of the polarization, thereby inducing the contrast. As a result, a clear pattern of domains in Anthracene film 404 became visible that were not readily apparent under normal viewing and illumination conditions.

As mentioned above, the concentration of the solution utilized can be controlled for a number of reasons. In addition to affecting the type of structure deposited, for example, film versus dentritic structure, control over the thickness and morphology of films can be achieved by varying the concentration of the solution. In addition, draining or pumping away the solution, varying the level of free surface and/or moving one or the other or both of substrate and container at a controlled growth rate can also achieve direct control over the in-plane growth rate.

In connection with Anthracene, actively controlling the growth rate in any one of these ways has typically produced films with submicron thickness for in-plane growth rates larger than 1 cm/hr. It is noted that in general this method does not provide direct control of the thickness of the film deposited, although the general trend for Anthracene is towards thinner films for higher growth rates. It is also noted that Anthracene films become discontinuous for higher in-plane growth rates. For example, FIG. 5 shows a fluorescence micrograph of an Anthracene film deposited onto an oxided silicon substrate at about 5 cm/hr. The light areas are Anthracene and the dark areas are the surface of the silicon substrate onto which the Anthracene was deposited. The image shows that an unexpected two-dimensional dendritic structure is formed. Additional imaging (inset) by polarized light microscopy showed that the crystallographic orientation is the same over the entire area shown (1 mm×1.25 mm).

The apparent mechanism that forces the selection of the highly oriented domains shown in FIGS. 4 and 5 is rather interesting. Small nuclei form early in the process and become elongated as the meniscus traces trajectory 132, 132′, 132″ (FIGS. 1A, 4, and 5, respectively) along the surface of the substrate. A preferred crystallographic direction is selected, since crystallites grow faster in certain low-index growth directions. Slow-growing nuclei with unfavorable orientations are left behind as the process proceeds, and the fast-growing domains increase rapidly in width, eventually squeezing out less favored orientations. The end result is the domain structure shown in FIG. 4, wherein single-crystal domains stretch almost the entire length of the surface in the growth direction, and, for Anthracene, have exceeded one centimeter in the direction transverse to trajectory. For Anthracene, adjacent domains have similar orientations, lying within a range of approximately ±10′.

Anthracene films can also be used as a substrate for overgrowth of other layers, for example, epitaxial layers. For example, an Anthracene/Pentacene system is an excellent model system for investigating the possibility of highly oriented heteroepitaxy because of the chemical and structural similarities of the two chemicals. Initial results for overgrowth of Pentacene are reported herein.

The lattice constants of Pentacene are similar to the lattice constants of Anthracene, except that the value of c is significantly larger for Pentacene. This is primarily a result of the fact that the Pentacene molecule is longer than the Anthracene molecule. In the present experiments, the phase of Pentacene at issue is the so-called “thin-film” phase, which is polymorphic. The present investigators' own recent determination of the lattice parameters for this polymorph, which differ only slightly from other published values, are: a=7.58 Å, b=5.91 Å, c=15.42 Å, and γ=90±0.2°. In the course of collecting the data of these experiments, the present investigators have also deduced that β≈95° for the Pentacene thin film phase. In both Pentacene and Anthracene, each layer of the corresponding crystal packs into a similar herringbone structure with two molecules per unit cell, and, therefore, the in-plane lattice constants are similar. Since the natural growth direction during vapor phase growth is normal to the a-b plane, the lattice mismatch in the c-direction does not affect the lattice matching at the hetero-interface between Anthracene and Pentacene.

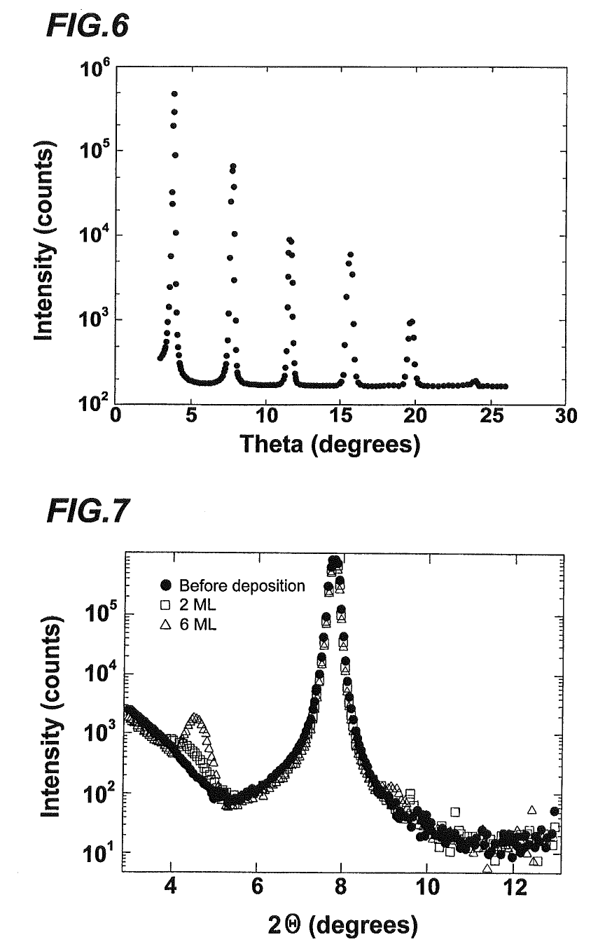

FIG. 6 shows the results of an x-ray diffraction θ-2θ scan of the sample shown in FIG. 5. Six orders of (001) reflections are clearly observed, indicating that the film is of good quality with the c* reciprocal lattice axis oriented normal to the surface. A layer spacing of d=9.18 Å was derived from this scan, which is consistent with the known crystal structure of bulk Anthracene. A small piece of this sample was mounted in a custom-built evaporation chamber coupled to an x-ray diffractometer for Pentacene evaporation.

Pentacene films were prepared in a custom-built vacuum evaporator, which was mounted in a four-circle x-ray diffractometer at the A2 station of the Cornell High Energy Synchrotron Source (CHESS). Substrates consisted of (100) p-type silicon wafers with a native oxide and an Anthracene film, prepared using the second variation of a CTSG method of the present invention as described above. Pentacene was evaporated from a tantalum boat under vacuum of 10⁻⁶ Torr and a substrate temperature of −15° C. The rate of deposition was 0.1 nm/min to 0.5 nm/min, as measured by a quartz crystal microbalance (QCM). The QCM was calibrated using AFM measurements in sub-ML thick films. Film growth was monitored during deposition at CHESS by using 10.0 keV x-rays (λ=1.239 Å) with a flux of approximately 10¹³ photons/sec, incident to the sample through a Be window. X-ray measurements were performed in-situ without breaking vacuum. A scintillation counter was used for measuring the scattered x-ray intensity. X-ray diffraction scans performed in-situ during the deposition of Pentacene are shown in FIG. 7. The Pentacene (001) and (002) reflections gradually sharpen and increase in intensity, in the characteristic of laminar growth. The positions of the reflections correspond to a layer spacing of d=15.4 Å, in good agreement with the established value for the “thin film” phase of Pentacene. Growth of Pentacene was stopped at approximately 6 monolayers.

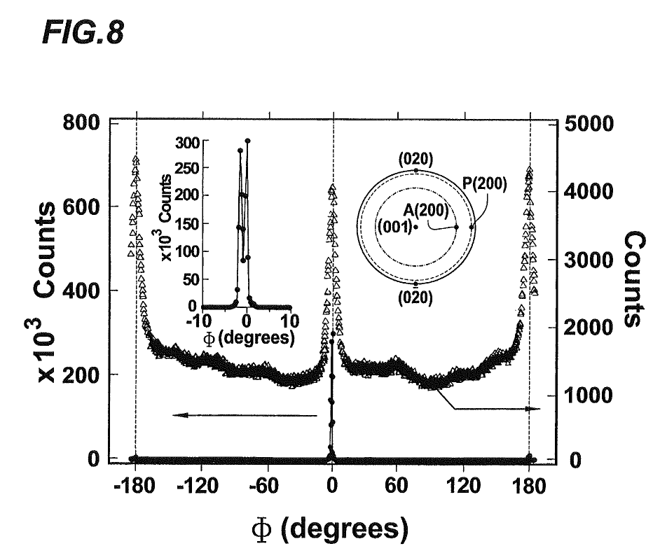

Grazing incidence x-ray diffraction scans were performed on additional Anthracene films and Anthracene films with Pentacene overlayers, in order to establish the in-plane orientation of both layers. A sample prepared in the same manner as the sample of FIG. 5, with a 40 nm thick Pentacene overlayer exhibited a planar, oriented dendritic surface morphology and was found by polarization microscopy to be predominantly (>95%) single crystal in nature. FIG. 8 shows an azimuthal scan on the (200) reflection of Anthracene (filled circles) for this sample. If the film were polycrystalline, composed of domains with a perfectly random distribution of azimuthal orientations, a continuous low intensity would be observed. Since we observe one dominant reflection at 0°, the film is predominantly single-crystal. However, the left-hand inset shows evidence for two grains with about a 1° misorientation relative to each other.

To assist the reader in interpreting the orientations of the Anthracene and Pentacene crystal planes in the aligned samples, a stereographic projection is included as the right-hand inset of FIG. 8. The polar angle between the (001) reflection and the (200) reflection is β*=100−β where β is the real-space angle between the a and c lattice vectors of the thin-film crystal structure and β* is the corresponding polar angle in the stereographic projection. The Anthracene (200) is observed at β*=55.4°, consistent with the structure of Anthracene. The path of the scan corresponding to the Anthracene (200) data shown in FIG. 8 is indicated in the right-hand inset by the red dashed line.

An additional piece of information about the Anthracene film can be obtained from FIG. 8: The sample has been oriented so that the scattering vector is perpendicular to the film growth direction at the azimuthal angle φ=0. Therefore, since the (200) reflection appears at φ=0, we conclude that the [200] direction is perpendicular to the Anthracene growth direction. In other words the domains shown in FIGS. 2 and 3 are oriented with their long axes parallel to the [010] crystallographic direction.

The data of FIG. 8 confirm that the individual planar dendrites in FIG. 5 have identical crystallographic orientations. Apparently, a combination of the preferred orientation imposed by the deposition process, and the links between adjacent branches in the structure is enough to select a single crystallographic orientation for the whole area. The origin of this two-dimensional dendrite structure is not presently understood, but it appears to be related to well-known growth instabilities, such as the Mullins-Sekerka instability, which may be induced by concentration gradients as molecules diffuse in the region of the meniscus and are depleted by being incorporated into the film.

FIG. 8 also shows a scan for the (200) reflection of Pentacene on the same sample (triangular data points), which exhibits strong reflections with a continuous low intensity in-between the reflections. The Pentacene (200) reflection is completely separated from the Anthracene (200) reflection because of different tilt of molecules, and hence of the unit cell. As a result of this difference, the Pentacene (200) is observed at β*=85°, which directly gives β=95° for the thin film phase of Pentacene. The path of the scan corresponding to the Pentacene (200) data is indicated in the inset by the blue dashed line. The background level for the Pentacene scan is about 1000 counts, so the fact that the intensity between the reflections is higher than 1000 indicates that there are some mis-oriented grains. Since the sample has a discontinuous structure with regions of the substrate visible (FIG. 5), it is reasonable that some fraction of the Pentacene film grows in a polycrystalline mode, hence the presence of the observed continuous ring in reciprocal space. The dominant aligned peaks are correlated with the growth direction of the Anthracene base layer, and also with the Anthracene crystallographic orientation. The reflection at φ=±180° is attributed to a crystal orientation with the [200] direction pointing in the opposite direction. Based on this information, the present investigators have found that the preferred Anthracene/Pentacene epitaxial relationship is (001)ₐ∥(001)ₚ and [100]ₐ∥[100]ₚ.

The present investigators have not observed strain effects on Pentacene layers. Rather, all of the observed reflections, including (001), (200), (020), and (110) appear to be at their unstrained positions. This may be interpreted as evidence of incommensurate epitaxy. On the other hand, the ratios of the Anthracene and Pentacene lattice parameters fall very close to the rational fractions 9/8 (within 0.3%) and 51/50 (within 0.1%). When the ratios are rational numbers, the growth is classified as “coincident epitaxy”, where every n^{th} site of the substrate lattice is coincident with every m^{th} site of the overlayer's lattice, and n and m are integers. This may help to explain the high degree of azimuthal orientation observed for Pentacene growth on Anthracene, since the coincidence effect would reduce the interface energy between the layers relative to random orientations. There is also a possibility of strain effects during the initial stages of nucleation and growth of the Pentacene films that have relaxed by the time the film reaches its final thickness. If the film were fully coherent during the initial stages of nucleation, then the orientation would be determined at that time. Another effect that can cause oriented epitaxy is orientation by surface features such as step-edges or facets. Presently, it is not known which of these effects is the dominant one.

Implementation of a submersion-type CTSG method of the present invention has demonstrated successful growth of thin structures with macroscopic single-crystal domain sizes. The present invention is very general, and may be extended to the growth of materials other than Anthracene. It has also been demonstrated that a Pentacene layer can be grown as a highly oriented film on top of an Anthracene thin structure grown in accordance with the present invention. The Pentacene overlayer can maintain the crystallographic orientation of the Anthracene layer. The observed high-degree of ordering is generally surprising, since there is a significant degree of lattice mismatch between the two materials, and the interface interaction between the two materials is very weak.

### Writing-Type Implementation

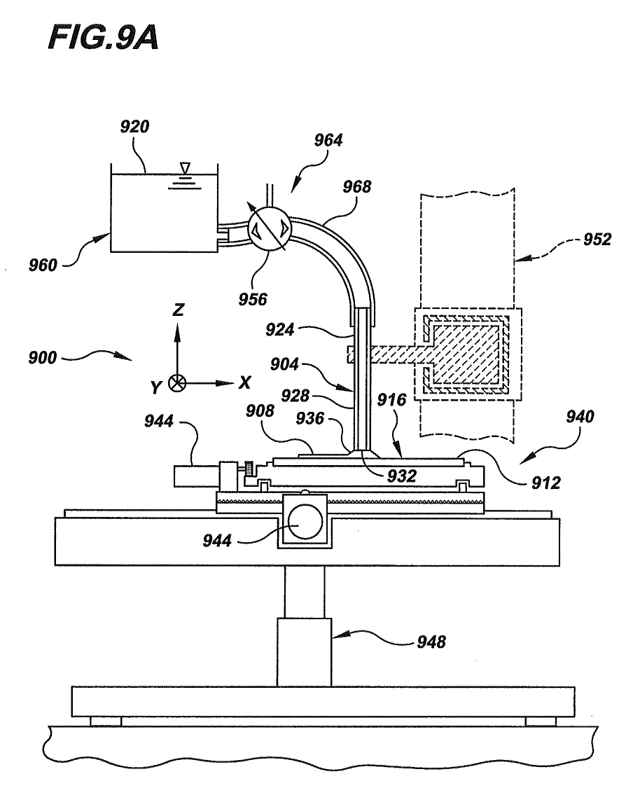

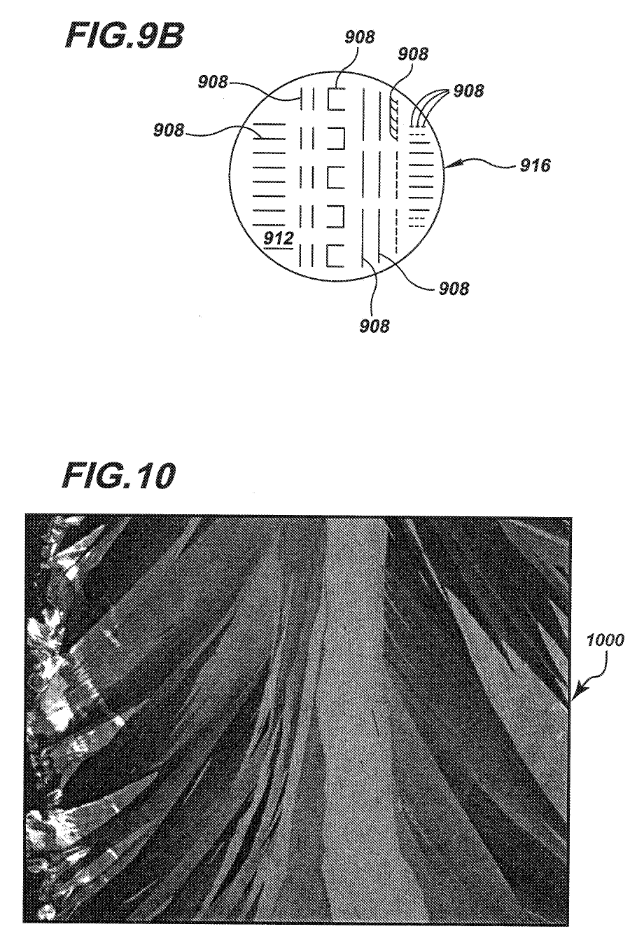

In addition to the submersion-type and mask-type implementations described above, the present inventor has discovered a novel and highly useful implementation that involves delivering the precursor solution to one or more writing instruments, or “meniscal pens,” that, when placed into close proximity to a growth surface, for example, the surface of a planar substrate, each form a meniscus relative to the growth surface. Each meniscus is moved relative to the growth surface, either by moving the corresponding pen or the substrate, or both, so as to form a thin crystalline “line” in accordance with the molecular assembly process described above in connection with FIGS. 1A-8. It is noted that while each meniscal pen may be considered to form a line of thin crystalline material, a group of meniscal pens may be ganged with one another so that the lines from the individual pens abut or overlap one another to effectively form a continuous film of crystalline material. FIGS. 9A, 14, and 15A-B are directed to exemplary embodiments relating to writing-type implementations of the present invention. FIG. 9B illustrates a set of thin crystalline lines 908 that a writing-type CTSG system can provide, FIGS. 10 and 12 illustrate actual crystalline lines drawn using a writing-type CTSG system of the present invention, and FIGS. 11A and 13 illustrate two types of electrical devices, specifically, a transistor 1100 and a photovoltaic cell 1300, that may be made using CTSG techniques of the present invention. FIGS. 9A-15B are described below in detail.

FIG. 9A illustrates a writing-type CTSG system 900 that includes a meniscal pen 904 used to “write” one or more thin crystalline lines 908 (only one shown in FIG. 9A) of a semiconductor material onto the growth surface 912 of a substrate 916 using a precursor solution 920, for example, any of the solutions described above in connection with FIGS. 1A-8. Like other substrates described in this disclosure, surface 912 of substrate 916 may be any one or more (in differing regions and/or layers) of amorphous, polycrystalline, or monocrystalline. In this connection, substrate 916 may be a “blank” substrate or a substrate that has been processed, for example using conventional microelectronics processing techniques and/or one or more of the techniques disclosed herein, to include one or more layers and/or regions that will become functional components of electrical devices (not shown) formed on the substrate. In this example, pen 904 comprises a capillary tube 924 having a tip end 928 that defines a meniscal region 932.

During use, growth surface 912 of substrate 916 is moved into proximity to pen 904 (or vice versa in some alternative embodiments) so that a meniscus 936 of solution 920 forms between meniscal region 932 of the pen and the growth surface. As will be appreciated, capillary tube 924 may have any inside diameter suitable for holding solution 920 therein and forming meniscus 936 suitable for the growth of thin crystalline lines 908 to take place. In one example, the inside diameter of capillary tube 924 is selected to write lines 1 mm wide. In other examples, inside diameter may be selected, for example, to write lines of any width in a range of 20 nanometers to 2 mm. As will be further appreciated, meniscus 936 corresponds to meniscus 128 of FIG. 1A and, thus, all of the description of the molecular assembly/growth process attendant meniscus 128 is likewise applicable to meniscus 936 of FIG. 9A. Therefore, that description is not repeated here for brevity. It is noted that the thickness of thin crystalline line 908 shown is much greater than would actually occur. The large thickness is shown merely for purposes of illustration. In this example, CTSG system 900 includes a moveable stage 940 that moves substrate 916 in an X-Y plane so that the system writes the one or more crystalline line(s) 908 at the desired location(s). As those skilled in the art will readily appreciate, moveable stage 940 may be made moveable in any suitable manner, such as using stepper motors 944 or any other suitable actuator.

This example also shows CTSG system 900 as having an actuator 948 for moving meniscal pen 904 toward and away from substrate 916 in the Z-direction as necessary to initiate and terminate, respectively, the drawings of lines 908 on growth surface 916 of the substrate. In this connection, it will be appreciated that by an appropriate combination of X-Y movements by moveable stage 940, thin crystalline line 908 may be drawn on growth surface 916 along virtually any trajectory. In conjunction with suitable X-Y movements by moveable stage 940, suitable Z-direction movements provided by actuator 948 can be used to allow meniscal pen 904 to provide multiple lines 908 having any trajectories desired. In this connection, see FIG. 9B, which as mentioned above, shows growth surface 912 of substrate 916 containing multiples lines 908 having differing trajectories along the growth surface. In alternative embodiments and examples, substrate 916 may be held on a fixed stage or other device, and meniscal pen 904 may be moved using an X-Y or an X-Y-Z actuating mechanism 952. In yet other embodiments and examples, substrate 916 may be moved in, for example, the X direction, and meniscal pen 904 may be moved in the Y-direction, much in the way that a desktop inkjet-type paper printer moves the paper and inkjet cartridge. It is noted that instead of providing a Z-direction movement for stopping and starting lines 908, a mechanism, for example, reversible pump 956, may be provided for drawing solution 920 at tip end 928 back into capillary tube 924 so as to withdraw meniscus 936 from meniscal region 932. CTSG system 900 will typically, but not necessarily, include a reservoir 960 for holding solution 920 prior to being provided to meniscal pen 904. If reservoir 960 is spaced away from meniscal pen 904, a solution delivery system, such as delivery system 964 that includes pump 956 and tubing 968, may be provided to deliver solution 920 from the reservoir to the pen. In another example, the pressure on the interior of reservoir 960 could be regulated, for example, using an air-pressure regulator (not shown). When it is desired to write with meniscal pen 904, the interior of reservoir 960 would be placed under a relatively small internal pressure to force a droplet to form

FIG. 10 illustrates the crystalline nature of a segment 1000 of a line drawn using a writing-type CTSG system of the present invention. For example, segment 1000 could be a segment of any one of lines 908 of FIGS. 9A and 9B if CTSG system 900 is set up properly. In FIG. 10, segment 1000 is made of triisopropylsilyl-pentacene and is grown (drawn) on a thin film of gold (not shown). The polarization contrast reveals the domain structure of the semiconductor material, which has remarkably large grain size that exceeds one millimeter along the length of the line in some areas.

Recent work has focused on bis(triisopropylsilylethynyl)-pentacene solutions with various concentrations from 0.1% to 8% by weight in toluene. Writing speeds of 0.1 cm/min to 10 cm/min have been used. (Other speeds may be used to suit particular set-ups and other parameters, such as solvent evaporation time.) It has been observed that both solution concentration and writing speed appear to have an effect on the thickness and grain size of the films grown. Presently, no attempt has been made to vary the temperature of the substrate, although temperatures up to at least 90° C. may have a desirable effect on the properties of the film.

Important characteristics of a writing-type CTSG technique of the present invention include:
1) It is a low-temperature process for depositing thin films on arbitrary substrates, including glass, silicon, metal, and polymers. The substrate does not need to be crystalline.
2) It is a single-step process that is distinguishable from “processing-type” methods such as laser recrystallization and laser annealing. It is also distinguishable from methods that depend on bonding thick layers, followed by a thinning step.
3) It produces films with thickness less than one micron with extremely large crystalline grain sizes, for example, 0.1 mm to 1 mm along the writing direction and 0.01 mm to 0.1 mm transverse to the writing direction (see FIG. 10).
4) It is a direct-write process in which patterns can be directly written onto a surface. This reduces the number of patterning steps needed to produce structures for electronic devices, especially organic devices.
5) It is a process that is not limited to planar substrates. Curved and flexible substrates can be easily accommodated.
   The present inventor is unaware of any other process for a thin-film system that meets all five of these criteria. Furthermore, it appears that large grain sizes can be obtained relatively easily for many soluble small molecules.

FIG. 11A illustrates one of many types of electrical devices, here an organic field-effect transistor (OFET) 1100, that can be made using any of the techniques of the present invention, such as the writing technique illustrated in connection with CTSG system 900 of FIGS. 9A-B. In this example, OFET 1100 includes a gate contact layer 1104, a gate dielectric layer 1108, a source/drain layer 1112, and a channel layer 1116. Gate contact layer 1104 may be made of any suitable material, such as doped crystalline silicon, doped polysilicon, or metal (e.g., Au, Ag, Cu, Al), and any combination thereof, among others, and deposited in any suitable manner, such as thermal evaporation, deposition from a solution containing a nanoparticles suspension (typically silver nanoparticles), etc. Gate dielectric layer 1108 may be either inorganic, such as silicon dioxide, or organic, such as poly(methyl-methacrylate), and may likewise be deposited/grown in any suitable manner. Source/drain layer 1112 may be made of any suitable material, such as an inorganic or organic conductive material, such as a metal or doped silicon, among others. Source/drain layer 1112 of OFET 1100 defines a source 1120 and a drain 1124 spaced apart so as to define the channel 1128 of the OFET. As those skilled in the art will appreciate, the distance between source 1120 and drain 1124 define the length of channel 1128, while the width of the channel extends in a direction perpendicular to the face of the page containing FIG. 11A. In the example shown, gate contact layer 1104 is crystalline silicon, gate dielectric layer 1108 is silicon dioxide, and source/drain layer 1112 is gold.

In this example, channel layer 1116 is made of an organic semiconductor material deposited in accordance with any one of the techniques of the present invention. For example, FIG. 11B shows ten OFETs 1100A-J arranged into two rows 1132A-B, with OFETs 1100A-E each being complete with a channel layer 1116A and OFETs 1100F-J not yet having a channel layer. This sort of configuration of OFETs 1100A-J could readily be made using writing-type CTSG system 900 of FIG. 9A. For example, on one pass, meniscal pen 904 of FIG. 9A could be used to draw channel layer 1116A over the channel regions 1136A-E of OFETs 1100A-E in row 1132A. Then, in a subsequent pass (or as part of a continuous loop), meniscal pen 904 of FIG. 9A could be used to draw a similar channel layer (not shown) over the channel regions 1136F-J of OFETs 1100F-J in row 1132B. In other embodiments, such as CTSG systems 1400, 1500 of FIGS. 14 and 15A-B, respectively, both crystalline thin lines could be written simultaneously over the two rows 1132A-B of OFETs 1100A-J.

As those skilled in the art will appreciate, because electric current flows through OFETs 1100, 1100A-J, they can be used as light-emitting devices. For example, using interdigitated gold source and drain electrodes and a polycrystalline tetracene thin film for the channel layer, both positive charges (holes) and negative charges (electrons) are injected from the gold electrodes into the channel layer, thereby leading to electroluminescence from the tetracene.

FIG. 12, which is similar in nature to FIG. 10, illustrates the crystalline quality of a segment 1200 of line 1132A of FIG. 11B over OFET 1100A when that line is made of triisopropylsilyl-pentacene. As noted above, line 1132A provides channel layer 1116A of OFET 1100A. In FIG. 12, the dark vertical line near the center is the space between source 1120A and drain 1124A that defines channel 1128A of OFET 1100A. The polarization contrast reveals the domain structure of channel layer 1116A, which has remarkably large grain size that exceeds one millimeter along the length of the line in some areas.

Those skilled in the art will readily appreciate that OFETs 1100, 1100A-J of FIGS. 11A-B are merely illustrative of the many types of electrical devices that can be made using CTSG techniques of the present invention. Indeed, even OFETs 1100, 1100A-J may be constructed in other ways. For example the layers may be deposited in reverse order, i.e., with channel layer 1116, 1116A on the bottom and gate contact layer 1104 on the top. Of course, care must be taken to ensure that once a particular layer is formed, the forming of any subsequent layers does not destroy the functionality of the layer(s) already formed, as might occur, for example, if high-temperature processing were to be done after depositing high-temperature-intolerant organic thin crystalline structures. In addition, it is noted relative to the explicit example of FIGS. 11A-B that while only channel layer 1116, 1116A was deposited using a technique of the present invention, in other examples more than one layer may be deposited using any one or more of the techniques disclosed herein.

FIG. 13 contains another example of an electrical device that can be made using one or more techniques of the present invention. FIG. 13 illustrates a photovoltaic (PV) cell 1300 in which one or more layers are deposited using at least one of the techniques disclosed herein. In this example, PV cell 1300 includes a base substrate 1304 of polyethylene terephthalate and a transparent conductive layer 1308, in this case indium tin oxide (ITO) deposited thereon. An electron conducting layer 1312, here a layer of poly(ethylene dioxythiophene)/poly(styrene sulfonic acid) (PEDOT:PSS) is deposited by conventional means on ITO conductive layer 1308. A layer 1316 of, for example, a soluble derivative of Pentacene, is deposited using a technique of the present invention, such as a writing technique (e.g., the writing technique described above in connection with FIGS. 9A-10 or below in connection with FIG. 14) or a submersion technique (e.g., the submersion technique described above in connection with FIGS. 1A-C). Next, an electron acceptor layer 1320 is deposited onto layer 1316 using either conventional techniques or a technique of the present invention, such as either of the writing and submersion techniques mentioned above relative to the Pentacene of layer 1316. In this example, electron acceptor layer 1320 is formed from a soluble layer of a derivative of fullerene (carbon-60). PV cell 1300 is finished with a metal cathode layer 1324. Other layers may also be inserted into PV cell 1300 shown to modify the characteristics of the device. As those skilled in the art will appreciate, suitable materials other than the exemplary materials explicitly mentioned may be used for the various layers of PV cell 1300 as appropriate for a particular design.

FIG. 14 illustrates another example of a writing-type CTSG system 1400 and technique that are in accordance with the present invention. At a high level, CTSG system 1400 may be largely the same as CTSG system 900 of FIG. 9A, except that CTSG system of FIG. 14 has a plurality of meniscal pens 1404A-J, rather than the single pen 904 shown in FIG. 9A. Due to the similarities and sameness, any features not shown in CTSG system of FIG. 14 may be assumed to be the same as or similar to such features of CTSG system 900 of FIG. 9A. In the specific example of FIG. 14, meniscal pens 1404A-J are of the capillary type and are fixed in relation to one another, i.e., they are not moveable independently of one another. Meniscal pens 1404A-J may be considered to be organized into two banks 1408A-B. In addition, in this example the flow of solution 1412 to each meniscal pen 1404A-J is individually controlled so that for any writing operation, that pen can be either active or inactive. If active, a meniscal pen 1404A-J will draw a thin crystalline line 1416A-J on the substrate 1420, and, if inactive, no line will be drawn.

The inter-pen spacing of meniscal pens in each bank 1408A-B may be selected based on the design criteria at issue, which will likely be dictated by the writing operation that CTSG system 1400 is designed to perform. For example, if CTSG system 1400 is designed to write multiple parallel lines having centerlines spaced from one another by a distance S, meniscal pens 1404A-E in bank 1408A may have a centerline spacing of S if only those pens will be used for that writing operation. Alternatively, if both banks 1408A-B will be used to write the lines having centerline spacing distance S, then the inter-pen spacing in each of the banks may be 2×S if pens 1404F-J in bank 1408B are staggered by a distance of S relative to pens 1404A-E in bank 1408A. In another example, where banks 1408A-B are intended to both be used separately to write lines having a centerline spacing S and be used together to write an essentially continuous film, the inter-pen spacing in each bank will be S and the pens 1404F-J in bank 1408B will be staggered by a distance of S/2 relative to pens 1404A-E in bank 1408A. In this latter example, the widths of lines 1416A-E of bank 1408A and the widths of lines 1416F-J of bank 1408B would be engineered so that the lines of one bank at least abut the lines of the other bank so that the resulting film is essentially continuous. While each bank 1408A-B is shown as having only five meniscal pens 1404A-J, alternative embodiments may have banks each containing tens, hundreds, or thousands of such pens. In other embodiments only one bank of meniscal pens may be provided. In yet other embodiments, the meniscal pens may be individually moveable and/or moveable in subgroups. Still other embodiments can have yet additional differences. However, it is impractical to attempt to cover all possible embodiments. That said, all such alternative embodiments will be covered by the broad concepts of the present invention.

FIGS. 15A-B illustrate yet another example of a writing-type CTSG system 1500 and technique that are in accordance with the present invention. In this example, CSTG system 1500 includes a monolithic multi-meniscus pen 1504 that includes a sheet of material into which are formed a plurality of apertures 1508. Examples of materials of which pen 1504 can be made include metal, plastic, and glass, among others. Prior to, and/or during, each writing operation, apertures 1508 are provided with a suitable solution 1512 (FIG. 15B) that is a precursor to growing a crystalline thin film structure on a substrate, such as substrate 1516. Solution 1512 may be any of the solutions mentioned above relative to other examples described herein or other suitable precursor solution. Apertures 1508 are sized, shaped, and located so as to correspond respectively to the final sizes, shapes, and locations of the thin crystalline film structures 1520 deposited using CTSG system 1500 of FIG. 15B. As those skilled in the art will appreciate, each thin crystalline film structure 1520 when made of a suitable semiconductor material, such as any one of the organic semiconductor materials mentioned above, provides a functional component of one or more corresponding electrical devices, such as transistors, diodes, and photovoltaic cells, among others. The locations, sizes, and character of these devices will drive the sizes, shapes, and locations of structures 1520. Depending on the material used for pen 1504, apertures 1508 may be formed using any process suitable for that material. In one example, apertures 1508 are formed using laser machining. In other embodiments, apertures 1508 may be formed using another type of material removal technique, such as etching and electrical discharge machining, among others. In the example shown in FIG. 15A, it is noted that thin crystalline film structures 1520 have already been formed using pen 1504.

In other embodiments and as indicated by phantom lines in FIG. 15B, a monolithic multi-meniscus pen made in accordance with concepts of the present invention may include a plurality of capillary tubes 1524 (only one shown for convenience) that may be either formed integrally with the base plate 1528, for example, by machining, or formed separately from the base plate and later secured thereto. It will be understood that in such an alternative embodiment that all of the apertures would typically corresponding respective capillary tubes. For example, in the context of monolithic multi-meniscus pen 1504 of FIGS. 15A-B, each of apertures 1508 shown in FIG. 15A would have a corresponding capillary tube 1524 (FIG. 15B) configured so that the tips of the plurality of capillary tubes together define a flat plane (or other surficial shape) that is conformal to substrate on which the pen will be writing.

An example of a writing process using CTSG system 1500 of FIGS. 15A-B proceeds as follows. Substrate 1516, such as a wafer, on which thin crystalline film structures 1520 are to be deposited is provided. Substrate 1516 may be made of any of an amorphous, polycrystalline, or monocrystalline material, and any combination thereof, as dictated by a particular design. Depending on the state of fabrication of the electronic devices (not shown) aboard substrate 1516, the substrate may be a “blank” substrate or a substrate that has been processed, for example using conventional microelectronics processing techniques and/or one or more of the techniques disclosed herein, to include one or more layers and/or regions that will become functional components of the electrical devices formed on the substrate. Whatever the fabrication state of substrate 1516, the sizes, shapes, and locations of thin crystalline film structures 1520 to be deposited will be known, and monolithic multi-meniscus pen 1504 will be fabricated accordingly.

As will be appreciated by those skilled in the art, the fact that monolithic multi-meniscus pen 1504 is custom fabricated according to the configuration of the particular substrate 1516 at issue, a writing technique using a monolithic multi-meniscus pen the same as or similar to pen 1504 lends itself to situations in which the same pattern of thin crystalline film structures 1520 is needed on multiple substrates. Indeed, the writing technique being described can be readily likened to printing on paper using a printing press in which a single printing plate is used to print the same image multiple times, either on multiple sheets of paper or a continuous web of paper. In this connection, it is noted that substrate 1516 can be one of a number of like substrates or, alternatively, it could be a continuous web that will have multiple writings formed thereon using the same pen 1504. It is noted, however, that unlike printing, pen 1504 is not pressed into contact with substrate 1516. Rather, as described below, the microdroplets 1532 (FIG. 15B) of solution 1512 present at apertures 1508 when the apertures are filled with the solution are contacted with substrate 1516, thereby forming a meniscus (not shown) between pen 1504 and the substrate.

Once monolithic multi-meniscus pen 1504 has been provided, it is charged with solution 1512, i.e., the solution is provided to each of apertures 1508 so that it fills the apertures with a suitable amount of solution and it forms microdroplets 1532 that extend away from the pen. Apertures 1508 may be “charged” with solution by bringing pen 1504 into contact with the liquid solution to be used for the writing process and allowing capillary forces to draw the solution into each aperture. An alternative method would be to provide channels (not shown) on the reverse (non-writing) side of the structure that lead to a reservoir of the solution. Prior to writing, pen 1504 and substrate 1516 are brought into proper registration with one another and the pen and substrate are brought into close proximity to one another so that the microdroplets contact the substrate and the microdroplets form a meniscus relative to the surface of the substrate. When microdroplets 1532 are contacting substrate 1516, the substrate and/or pen 1504 are moved so as to draw thin crystalline structures 1520 at the desired locations in accordance with the crystal-forming process described above relative to FIGS. 1A-C and 4-8.

Exemplary embodiments have been disclosed above and illustrated in the accompanying drawings. It will be understood by those skilled in the art that various changes, omissions and additions may be made to that which is specifically disclosed herein without departing from the spirit and scope of the present invention.

What is claimed is:

1. A method of growing a crystalline structure of a semiconductor material, comprising:
providing a substrate that includes a growth region on which the crystalline structure will be formed;
providing a solution of dissolved molecules of the semiconductor material;
forming, with the solution, a meniscus on the growth region;
establishing, at the meniscus, an initial lateral seed front on the growth region; and
mechanically moving the meniscus relative to the growth region in a growth direction along the growth region so as to substantially continuously grow the crystalline structure on the growth region in the growth direction by first adding ones of the dissolved molecules to the initial lateral seed front to create a lateral growth front and then continually adding more of the dissolved molecules to the lateral growth front.

2. A method according to claim 1, wherein the solution has a free surface and said forming of the meniscus includes submerging at least a portion of the growth region in the solution so as to break the free surface.

3. A method according to claim 1, further including providing a meniscal pen having a meniscal region, wherein said forming of the meniscus includes forming the meniscus between the meniscal region of the meniscal pen and the growth substrate.

4. A method according to claim 3, wherein said providing of the meniscal pen includes providing an elongate capillary pen.

5. A method according to claim 3, wherein said providing of the substrate includes providing a substrate having a partially formed electronic device and said mechanically moving the meniscus results in the crystalline structure becoming an electrical component of the partially formed device.

6. A method according to claim 1, wherein said providing of the solution includes providing a solution of dissolved molecules of an organic semiconductor material.

7. A method of fabricating a crystalline structure of a semiconductor material, comprising:
providing a substrate having a surface;
providing a solution containing dissolved molecules of the semiconductor material of the elongate crystalline structure to be fabricated;
delivering the solution to a meniscal pen; and
writing a crystalline structure of the semiconductor material on the surface of the substrate using the meniscal pen.

8. A method according to claim 7, wherein said delivering of the solution to the pen includes delivering the solution to an elongate capillary pen.

9. A method according to claim 7, wherein said providing of the substrate includes providing a substrate in which the surface has thereon a partially formed electronic device, said writing of the crystalline structure including drawing an electrical component of the partially formed device.

10. A method according to claim 9, wherein said providing of the substrate includes providing a substrate in which the surface has thereon a partially formed transistor, said writing of the crystalline structure including drawing a channel of the partially formed transistor.

11. A method according to claim 9, wherein said providing of the substrate includes providing a substrate in which the surface has thereon a partially formed photovoltaic cell, said writing of the crystalline structure including drawing a semiconducting layer of the partially formed photovoltaic cell.

12. A method according to claim 7, wherein said providing of the solution includes providing a solution of dissolved molecules of an organic semiconductor material.

13. A method according to claim 7, further comprising:
providing a monolithic multi-meniscus pen having a plurality of apertures therein;
charging said plurality of apertures with the solution so as to form a plurality of microdroplets; and
writing via the plurality of microdroplets a plurality of crystalline structures of the semiconductor material on the surface of the substrate using the monolithic multi-meniscus pen.

14. A system for fabricating a crystalline structure of a semiconductor material on a substrate, comprising:
a reservoir for holding a solution containing dissolved molecules of the semiconductor material;
a meniscal pen having a meniscal region for delivering the solution from the reservoir to the substrate via a meniscus formed between said meniscal region and the substrate; and
a mechanism for controllably moving the meniscus relative to the substrate so as to form the crystalline structure on the substrate.

15. A system according to claim 14, further comprising the solution containing dissolved molecules of the semiconductor material of the crystalline structure.

16. A system according to claim 14, wherein said meniscal pen comprises a capillary tube having a tip, said tip including said meniscal region.

17. A system according to claim 14, wherein said mechanism draws the meniscus along the substrate during use so as to make the crystalline structure elongated.

18. A system according to claim 14, further comprising a plurality of meniscal pens each for delivering the solution from the reservoir to the substrate.

19. A system according to claim 14, wherein the system is for forming a pattern of a plurality of crystalline structures on the substrate, said meniscal pen comprising a monolithic multi-meniscus pen having a plurality of apertures arranged in the pattern of the plurality of crystalline structures.

20. A method of fabricating an electronic device, comprising:
providing a substrate;
providing a solution containing dissolved molecules of a semiconductor material;
forming an electrical device on the substrate, the electrical device having a crystalline semiconductor component, said forming of the electrical device including writing the crystalline semiconductor component;
forming other components of the electrical device; and
electrically connecting the electrical device to one or more other electrical devices aboard the substrate.

21. A method according to claim 20, wherein said writing of the crystalline semiconductor component includes writing the crystalline semiconductor component using a capillary meniscal pen.

22. A method according to claim 20, further comprising forming a plurality of electrical devices on the substrate, said forming of the plurality of electrical devices including writing a plurality of crystalline semiconductor components using a monolithic multi-meniscus pen.

23. A method according to claim 20, wherein said forming of the electrical device includes forming a transistor that includes a crystalline semiconductor channel formed by said writing of the crystalline semiconductor component.

24. A method according to claim 23, further comprising, prior to forming the crystalline semiconductor channel, forming a source and a drain of the transistor.

25. A method according to claim 20, wherein said forming of the electrical device includes forming a photovoltaic cell that includes a pair of crystalline semiconductor structures of opposite electrical types, at least one of the pair of crystalline semiconductor structures formed by said writing of the crystalline semiconductor component.
